(19) United States
(12) Patent Application Publication
(10) Pub. No.: US 2013/0306464 A1
(43) Pub. Date: Nov. 21, 2013

(54) SPUTTERING TARGET AND SPUTTERING APPARATUS AND SPUTTERING METHOD USING THE SAME

(71) Applicant: Panasonic Corporation, Osaka (JP)

(72) Inventor: HIROSHI HAYATA, Osaka (JP)

(73) Assignee: Panasonic Corporation, Osaka (JP)

(21) Appl. No.: 13/896,324

(22) Filed: May 17, 2013

(30) Foreign Application Priority Data
May 21, 2012 (JP) 2012-115155

(51) Int. Cl. C23C 14/34

(52) U.S. Cl. CPC C23C 14/3407
USPC 204/192.12; 204/298.12

(57) ABSTRACT

A rotary cylindrical sputtering target includes a plurality of target pieces bonded to the periphery of a backing tube, wherein the target pieces are arranged in the axis direction of the tube so that a gap is formed between the adjacent target pieces, wherein the gap has a straight section which extends from the outer periphery of the target pieces toward the axis of the backing tube, and a tapered section which is positioned between the straight section and the backing tube, and which slopes in the longitudinal direction of the straight section.

### CROSS REFERENCE TO RELATED APPLICATIONS

This application is entitled and claims the benefit of Japanese Patent Application No. 2012-115155, filed on May 21, 2012, the disclosure of which including the specification, drawings and abstract is incorporated herein by reference in its entirety.

### BACKGROUND

1. Technical Field

The technical field relates to a sputtering apparatus used in the production of a solar cell and the like.

2. Background Art

In recent years, photoelectric conversion efficiency of solar cells is required to be improved and the costs of solar cells are required to be reduced.

FIG. 6 shows a structure of the solar cell described in JP-A-2012-2 8718.

In FIG. 6, reference numeral 10 denotes a single crystal or polycrystalline silicon substrate, numerals 12, 13, 17 denote intrinsic semiconductor layers i and doped semiconductor layers n, p, numeral 16 denotes an anti-reflection film, numeral 18 denotes an insulating layer, numeral 19a denotes an ITO layer, numeral 19b denotes a metal layer, such as copper, and numerals 19c, 19d denote plating layers, such as Cu or Sn. In this solar cell, the single crystal or polycrystalline silicon substrate 10 absorbs a light 11 to form holes and electrons, and an electrode 14 and an electrode 15 collect, respectively, electrons and holes to generate electricity.

The ITO layer 19a of the solar cell is generally formed by a sputtering apparatus. For realizing the reduction of the cost of solar cell, the sputtering apparatus is required to be improved in the utilization of material so as to improve the productivity.

As a method for improving the productivity with respect to an apparatus for vacuum process, such as a sputtering apparatus, WO2009/107196 describes a method in which a plurality of substrates are placed on a single tray and subjected to treatment. In the vacuum process, a time for evacuation to cause the substrate to be in a vacuum state is required. When the plurality of substrates are subjected to evacuation at the same time, the productivity of the process is increased (that is, the treatment time per substrate is reduced).

Further, for improving the utilization of material, a sputtering apparatus using a rotary cylindrical target is widely used.

JF-A-2011-222634 describes a sputtering apparatus using a rotary cylindrical target. When a plurality of cells are subjected to treatment at the same time, a cylindrical target having a continuous length is used for improving the productivity. For obtaining a target having a continuous length, a target is formed from a plurality of pieces. Particularly, a sintered ITO target is easily fractured and a large piece of the sintered target is difficult to form, and therefore a continuous-length target is generally formed using a plurality of target pieces. The use of a plurality of target pieces also exhibits an effect such that the target is prevented from being fractured due to the thermal expansion caused upon sputtering.

WO2010/035718 discloses a cylindrical target formed from a plurality of pieces. A plurality of target pieces are fixed to a backing tube by a bonding material.

JP-A-2005-105389 discloses a technique for preventing the bonding material for bonding a plurality of target pieces from being sputtered.

Problems of a conventional technique are described with reference to FIGS. 7A to 7D.

In FIGS. 7A-7D, reference numeral 1 denotes a sputtering apparatus.

In FIGS. 7A-7D, numeral 11 denotes a load lock chamber. numeral 12 denotes a deposition chamber, and numeral 13 denotes a return chamber.

A cylindrical target 20 is placed in the deposition chamber 12. The target 20 is formed from a plurality of target pieces 20a, 20b, 20c and the like. A gap of about 0.1 to 1 mm is formed in target piece boundary portions 50a, 50b and the like. Such a gap is formed to prevent the problem that when the target is expanded due to the heat of sputtering, the target pieces are brought into contact with one another to cause a stress, so that the target pieces are fractured.

In FIGS. 7A-7B, general constitutional elements of the sputtering apparatus, a pump and piping for evacuating each chamber, a mass flow and piping for introducing a process gas to the deposition chamber, a power source and wiring for supplying electric power to the target, a purging gas line for permitting each chamber in the vacuum state to be under atmospheric pressure, a gate valve for permitting only the load lock chamber in the vacuum state to be under atmospheric pressure, and the like are not shown.

A plurality of solar cell substrates 40a, 40b, 40c and the like are disposed on a tray 30. The solar cell substrates 40a, 40b, 40c individually have a size such that one side is 100 to 200 mm. The solar cell substrates 40a, 40b, 40c are disposed on the tray 30 at intervals of about 10 to 20 mm.

The operation of the sputtering apparatus of FIGS. 7A-7D is described below.

As shown in FIG. 7A, the solar cell substrates 40a, 40b, 40c are disposed on the tray 30 using a robot or the like outside the sputtering apparatus. In this instance, the load lock chamber 11 is under atmospheric pressure, and a gate valve between the load lock chamber 11 and the deposition chamber 12 keeps the deposition chamber 12 and return chamber 13 in a vacuum.

Then, as shown in FIG. 7B, the tray 30 is transferred to the load lock chamber 11. A transfer mechanism is not shown. After the tray is transferred to the load lock chamber 11, the load lock chamber 11 is evacuated. After the load lock chamber 11 is evacuated to 1E-1 Pa, the gate valve between the load lock chamber 11 and the deposition chamber 12 is opened.

After the gate valve is opened, a process gas is introduced into the deposition chamber 12 to adjust the pressure. When the target 20 is formed from ITO, Ar and O₂ are used as the process gas. The pressure is adjusted to 1E-1 to 1E1 Pa. The pressure is adjusted using a valve capable of controlling the opening degree.

Then, by applying a voltage to the target by a not shown power source, a plasma is generated on the surface of the target. Ar ions in the plasma are accelerated by the target potential and collide with the target. This collision causes target atoms or molecules to be emitted from the target (or to be sputtered).

The tray 30 having disposed thereon the solar cell substrates 40a, 40b, 40c in a state such that a voltage is applied, to the target to start sputtering is transferred to the deposition chamber 12 as shown in FIG. 7C. The tray 30 is, as shown in FIG. 7D, transferred so that it completely passes through the front of the target 20 and enters the return chamber 13.

When the tray 30 passes through the front of the target 20 as shown in FIG. 7C, the target atoms or molecules sputtered from the target arrive at the solar cell substrates 40a, 40b, 40c, so that the target material is deposited on the substrates.

FIG. 8 is a cross-sectional view of the portion indicated by character X in FIG. 7C.

The deposition as shown in FIG. 7C is described in more detail with reference to FIG. 8.

The target 20 is fixed to a backing tube 60 by a not shown bonding material. The backing tube 60 has a hollow interior middle portion. Such a hollow structure of the backing tube is for flowing cooling water to prevent the target from being fractured due to the heat of sputtering and for placing a magnet 70 on the back surface of the target so as to improve the plasma density.

The target 20 and backing tube 60 are supported at both ends by not shown end blocks. Electric power and cooling water are supplied from the end blocks. The end blocks have incorporated thereinto a target rotating mechanism for rotating the target 20 and backing tube 60. The target rotating mechanism causes the target 20 to rotate round a rotating shaft C perpendicular to the plane of the paper of FIG. 8. The magnet 70 does not rotate and shuts out a plasma 80 on the side opposite the solar cell substrate 40 to promote sputtering from the surface of the target 20 opposite the solar cell substrate 40.

Thus, the target material is deposited, on the solar cell substrate 40. The conventional technique has a problem in that the component of the bonding material is mixed into the solar cell through the boundary portions 50a, 50b and the like of the target pieces 20a, 20b, 20c and the like, causing the deterioration of the properties of the solar cell.

The problem is described below.

FIG. 9A is a cross-sectional view of a general cylindrical target 20.

Target pieces 20a, 20b are fixed to a backing tube 60 by a bonding material 61. The bonding material 61 is an alloy having a low melting point comprising In, Sn, Zn, Pb, Ag, or the like.

A sintered target, such as an ITO target, is easily fractured, and a long cylindrical piece of the sintered target is difficult to form. Therefore, as mentioned above, a plurality of target pieces 20a, 20b and the like are combined, and bonded to a backing tube so that a gap 50a of about 0.1 to 1 mm is formed between the target pieces 20a, 20b.

The conventional technique, however, has a problem in that the bonding material is sputtered through the gap 50a.

The problem is described in detail with reference to FIG. 9B.

FIG. 9B is an enlarged view of the gap 50a between the target pieces, and corresponds to the portion indicated by character A in FIG. 9A. In the sputtering apparatus, argon ions in the plasma 80 are accelerated in the direction perpendicular to the target in a sheath region 81 by a voltage applied to the target and collide with the target. Most of the argon ions 82a collide with the target to sputter the target.

However, part of the Ar ions 82b go into the gap 50a and collide with the bonding material 61, so that the atoms or molecules constituting the bonding material 61 are expelled and deposited as impurities on the solar cell substrate 40.

The impurities deposited on the solar cell substrate 40 cause an impurity energy level in the semiconductor layer and serve as a recombination center of holes and electrons, so that the resultant solar cell has a reduced conversion efficiency.

In the above example, as shown in FIG. 10, the impurities sputtered through the gaps 50a, 50b, 50c, 50d between the target pieces 20a, 20b, 20c, 20d, 20e are deposited on the solar cell substrate 40 which has passed through above transfer paths 70a, 70b, 70c, 70d, so that the solar cell having the impurities deposited thereon is reduced in the conversion efficiency. The method for solving this problem is not disclosed in the above-mentioned patent documents (see JP-A-2012-28718, WO2009/107196, JP-A-2011-222634, and WO2010/035718).

The bonding material 61 sputtered through the gaps 50a to 50d between the target pieces 20a to 20e is also deposited on the surface of the target 20. The bonding material 61 has a low sputtering yield, as compared to the target material, and therefore serves as a mask for the spurring by argon ions. As a result, a protrusion is formed on the surface of the target. This is called a nodule.

An electric field is concentrated in the nodule to increase the temperature, so that oxidation proceeds to cause abnormal discharge. As oxidation proceeds, the nodule becomes non-conductive, so that positive charges are accumulated in the nodule. When positive charges are accumulated in an amount of a certain threshold or more, the charges are combined with electrons on the target 20, causing abnormal discharge. The abnormal discharge is likely to cause particles to be generated or cause the target to be fractured. Therefore, when a nodule is generated, the sputtering apparatus must be stopped for maintenance of removing the nodule deposited on the target 20. Thus, the generation of a nodule causes the productivity of the sputtering apparatus to be lowered.

As described above, the conventional technique has a problem in that the bonding material is sputtered through the boundary portions of the target pieces to generate a nodule, causing the productivity of the sputtering apparatus to be lowered. The method for solving the problem is not disclosed in the above-mentioned patent documents (see JP-A-2012-28718, WO2009/107196, JP-A-2011-222634, and WO2010/035718).

A technique for preventing the bonding material 61 from being sputtered is described in JP-A-2005-105389. The technique of JP-A-2005-105389 is described with reference to FIG. 11. In FIG. 11 and FIGS. 9A and 9B, like constitutional elements are indicated by like reference numerals.

In the technique of JP-A-2005-105389, an end face e1 of a target piece 21a opposite a target piece 21b and an end face e2 of the target piece 21b opposite the target piece 21a slope at the same angle in the axis direction of a backing tube 60, and there is no bonding material in the direction to which argon ions 82b move, making it possible to prevent the bonding material from being sputtered.

However, the argon ions accelerated, in a sheath region 81 include argon ions 82C having a sloping component, though they are in a slight amount, and therefore the construction described in JP-A-2005-105389 cannot satisfactorily prevent the bonding material from being sputtered.

Further, in the construction of FIG. 11, a corner 22 of the target piece 21a has an acute angle, and, when a sintered target, such as ITO, is formed from, these target pieces, a problem arises in that the target is likely to suffer the formation of a crack.

When a target having a crack formed therein is used, the target is fractured during the production and thus the production apparatus must be stopped, leading to a problem in that the productivity is lowered.

Thus, the method for solving the above problems is not disclosed, in any of the above-mentioned patent documents (see JP-A-2012-28718, WO2009/107196, JF-A-2011-222634, WO2010/035718, and JP-A-2005-105389).

The present invention solves the problems accompanying the conventional technique, and an object of the invention is to provide a sputtering target which is advantageous in that the contamination by the bonding material in the deposition using a rotary cylindrical target having a plurality of target pieces can be suppressed, improving the quality and productivity.

### SUMMARY OF THE INVENTION

For achieving the above object, in an aspect of the invention, there is provided a rotary cylindrical sputtering target having a plurality of target pieces bonded to the periphery of a cylindrical backing tube, wherein the target pieces are arranged in the axis direction of the cylindrical backing tube so that a gap is formed between the adjacent target pieces, wherein the gap has a straight section which extends from the outer periphery of the target pieces toward the axis of the cylindrical backing tube, and a tapered section which is positioned between the straight section and the cylindrical backing tube, and which slopes in the longitudinal direction of the straight section.

When the slope is expressed, by an angle α of one of the target pieces constituting the gap, the shape of an end face of the target piece is formed from a straight portion extending from the surface of the target toward the center of rotation, and a tapered, portion having an angle to the straight portion of more than 90%, and the tapered portion of one of the adjacent target pieces can be disposed on the extension of the straight portion of another one of the adjacent target pieces. The angle to the straight portion of more than 90° indicates 90 to less than 180°.

In the invention, the shape of the gap formed between the adjacent target pieces has a straight section which extends from the outer periphery of the target pieces toward the axis of the cylindrical backing tube, and a tapered section or a curved section, which is positioned between the straight section and the cylindrical backing tube, and which slopes in the longitudinal direction of the straight section. Argon ions enter the gap from the outer periphery of the target pieces and move through the straight section, and collide with the wall surface forming the tapered section or curved section, and hence do not collide with the bonding material on the surface of the cylindrical backing tube. Therefore, the occurrence of abnormal discharge due to the contamination by the bonding material and the formation of a nodule, and the target fracture are prevented, making it possible to achieve deposition with high quality and high productivity. Further, the straight section of the gap is present on the outer periphery side of the target pieces, and therefore, in the surface of the target, there is no portion to be processed into an angular shape, and thus the lowering of the operating efficiency of the apparatus due to the formation of a crack can be prevented.

### BRIEF DESCRIPTION OF THE DRAWINGS

In the drawings:

FIG. 1 is an enlarged cross-sectional view of an essential portion of a sputtering target according to a first embodiment of the invention;

FIG. 2 is an explanatory view illustrating the operation of FIG. 1;

FIGS. 3A and 3B are explanatory views illustrating a distance D of the tapered section;

FIG. 4A is an enlarged cross-sectional view of an essential portion of a sputtering target according to a second embodiment of the invention, and FIG. 4B is an explanatory view illustrating the operation of FIG. 4A;

FIG. 5A is an enlarged cross-sectional view of an essential portion of a sputtering target according to a third embodiment of the invention, and FIG. 5B is a cross-sectional view of an example of the modification of FIG. 5A;

FIG. 6 is a cross-sectional view of a solar cell;

FIGS. 7A to 7D are explanatory views illustrating a sputtering apparatus;

FIG. 8 is a cross-sectional view of the portion indicated by character X in FIG. 7C;

FIGS. 9A and 9B are cross-sectional views of a conventional cylindrical sputtering target;

FIG. 10 is a view showing problems of the conventional sputtering target; and

FIG. 11 is a view showing problems of the conventional sputtering target.

### DETAILED DESCRIPTION OF THE INVENTION

Hereinbelow, embodiments of the invention will be described with reference to the accompanying drawings.

In the invention, the parts or portions having the same actions as in the above-mentioned conventional example are indicated by the same reference numerals as those in the conventional example.

### FIRST EMBODIMENT

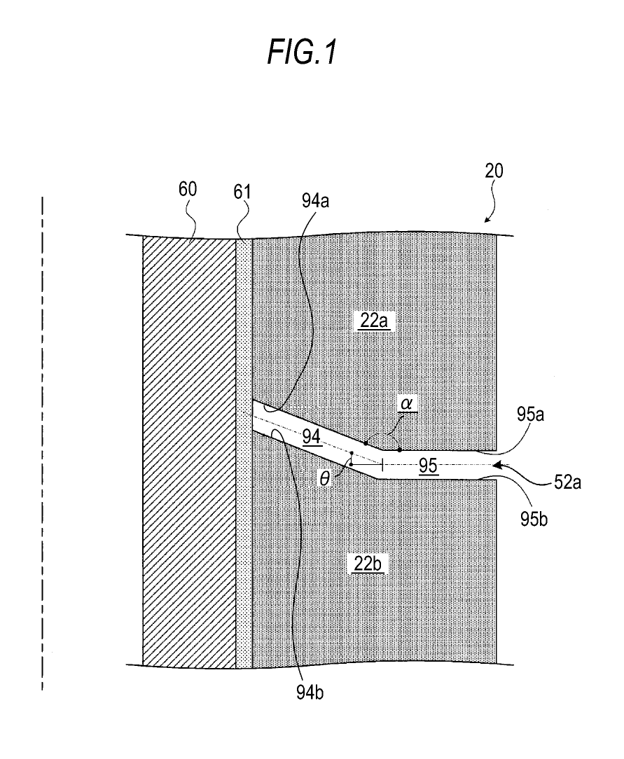

FIG. 1 shows a rotary cylindrical sputtering target 20 according to the first embodiment of the invention. Specifically, FIG. 1 shows a portion corresponding to the portion of the conventional example shown in FUG. 11.

In the sputtering target 20 of the conventional example shown in FIG. 11, the gap 51a formed between the adjacent target pieces 21a, 21b is foraged solely from the passage sloping in the axis direction of the backing tube 60. In the first embodiment of the invention, a gap 52a formed between adjacent target pieces 22a, 22b is formed to include a straight section 95 and a tapered section 94, wherein the straight section 95 has one end which opens to the outside at the outer periphery of the target pieces 22a, 22b, and has another end which extends in straight line toward a cylindrical backing tube 60, and the tapered section 94 is positioned between the straight section 95 and the cylindrical backing tube 60 and slopes at an angle θ in the longitudinal direction of the straight section 95. The tapered section 94 is connected to the another end of the straight section 95. Specifically, the gap 52a has a width of 0.1 to 1 mm. The target pieces 22a, 22b individually have a thickness of 5 to 20 mm. The angle θ is 5 to 30°.

The end face of the target piece 22a opposite the end face of the target piece 22b is formed from a straight portion 95a and a tapered portion 94a. The end face of the target piece 22b opposite the end face of the target piece 22a is formed from a straight portion 95b and a tapered portion 94b.

The straight section 95 is formed from the straight portion 95a of the target piece 22a and the straight portion 95b of the target piece 22b. The tapered section 94 is formed from the tapered portion 94a of the target piece 22a and the tapered portion 94b of the target piece 22b. Further, the tapered portion 94b of the target piece 22b is disposed on the extension of the straight portion 95a of the target piece 22a.

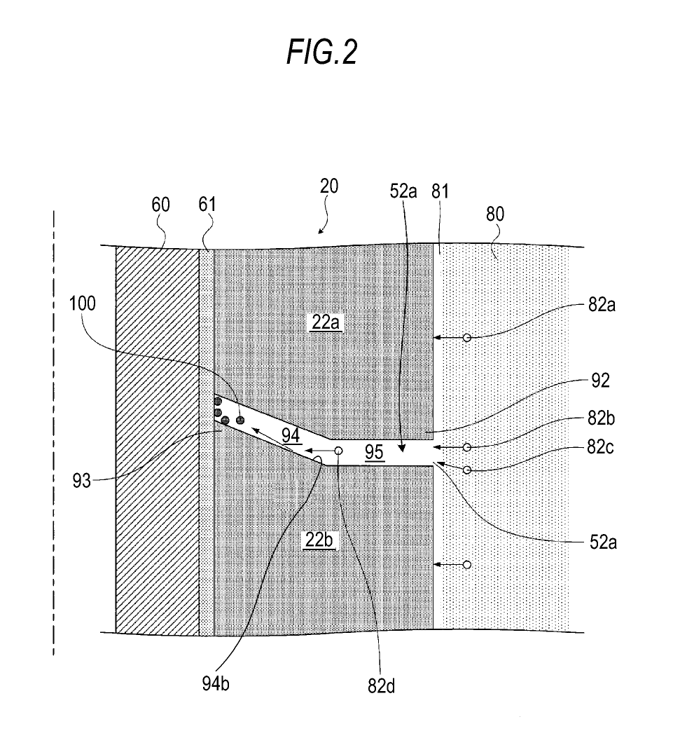

The operation of a sputtering apparatus using the rotary cylindrical sputtering target 20 shown in FIG. 1 in a deposition chamber 12 is described with reference to FIG. 2.

In the sputtering target 20, the straight section 95 of the gap 52a is disposed in the outer periphery of the target, and therefore it is possible to cause all argon ions 82b, 82c entering the gap 52a to move in the direction perpendicular to the surface of the target. The resultant argon ions 82d moving in the same direction collide with the tapered portion 94b of the tapered section 94, and therefore there is no fear that the argon ions having an angle of incidence which is the same as the angle of the tapered section 94 collide with the bonding material. Thus, it is possible to reduce the amount of the bonding material 61 sputtered and deposited on the solar cell substrate.

Further, the argon ions 82d, all of which have been caused to move in the same direction in the straight section 95, surely sputter the tapered portion 94b, making it possible to deposit a target material 100 on the bonding material 61. By virtue of this, even when high-energy argon ions or argon reaches the bonding material 61, the bonding material can be prevented from being sputtered.

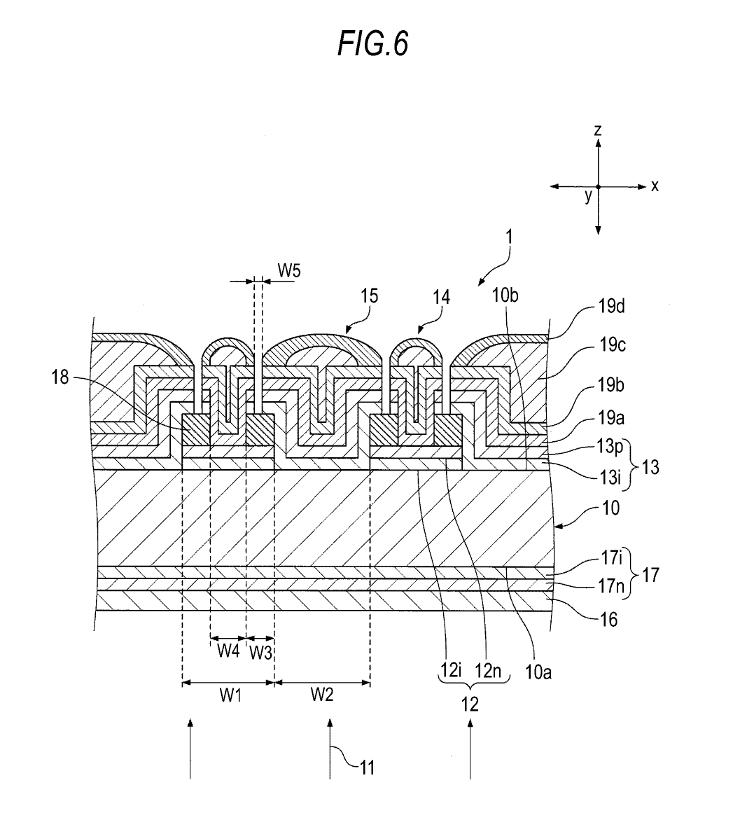

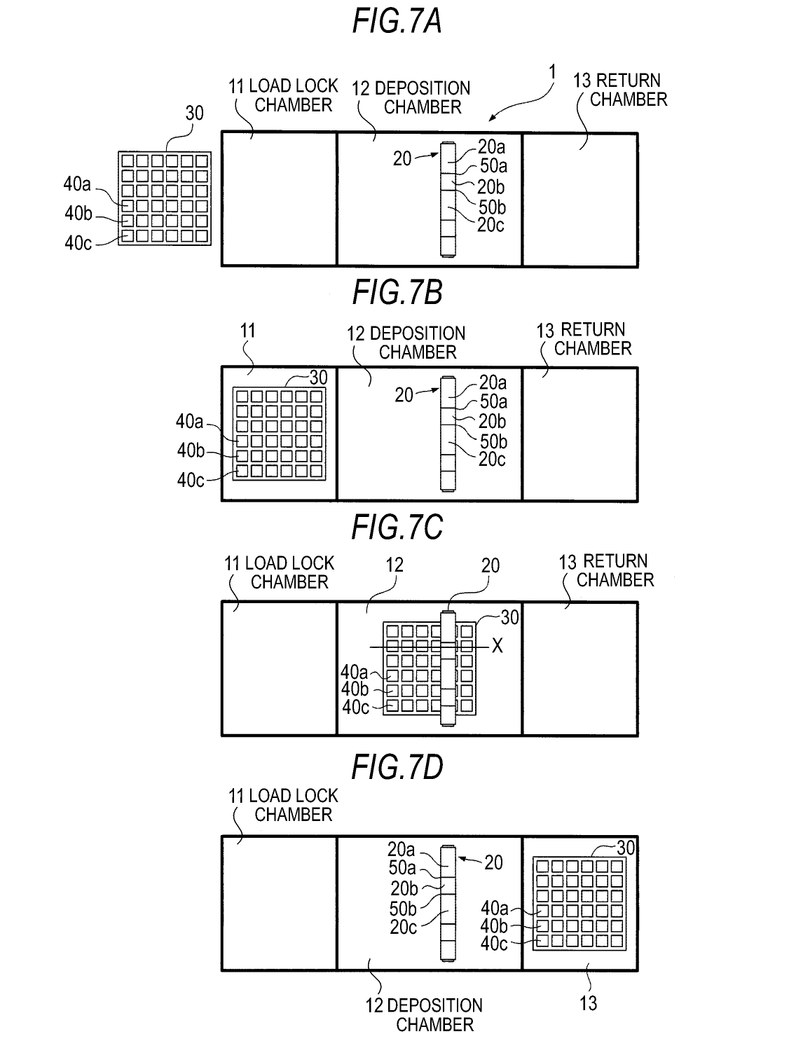

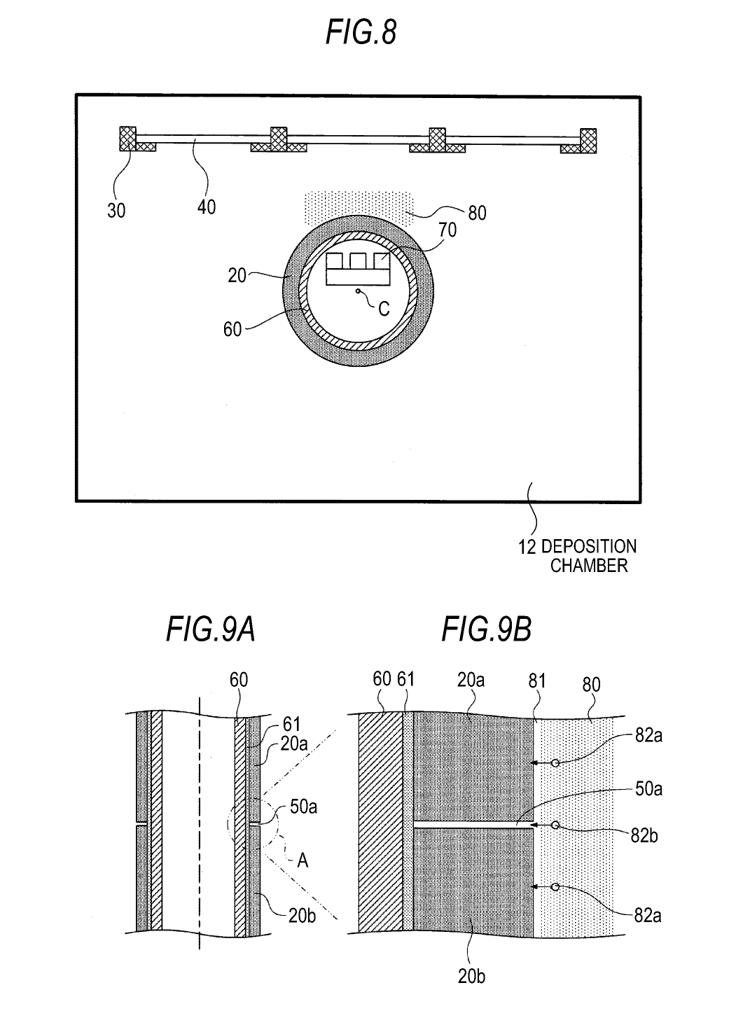

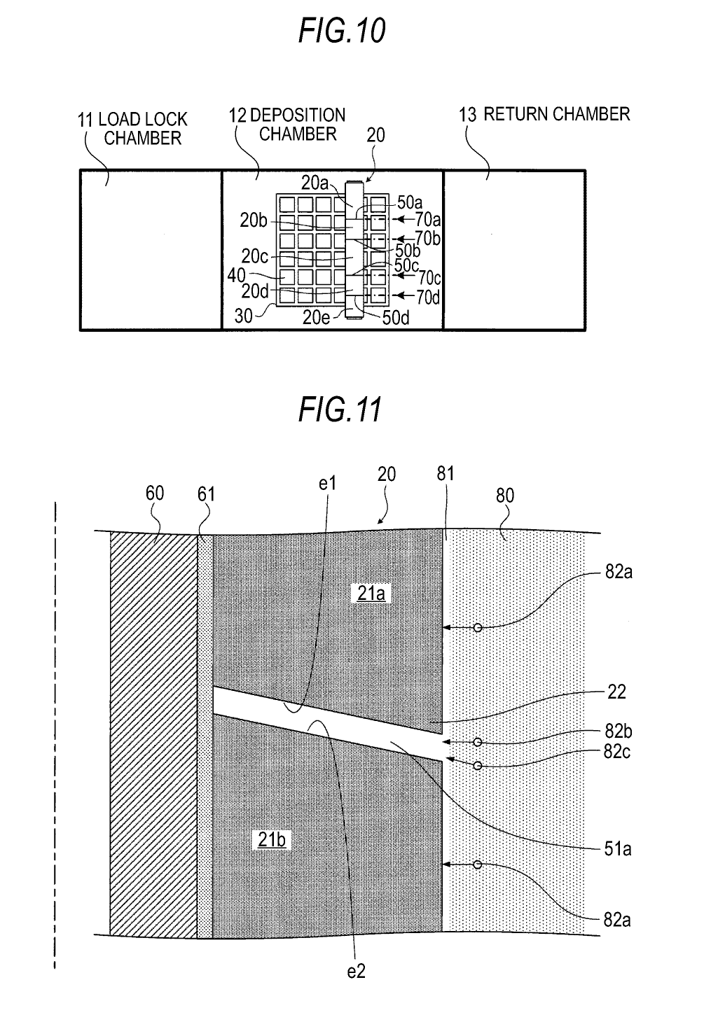

As mentioned above, the amount of the bonding material 61 deposited on the solar cell substrate 40 can be reduced. Therefore, when a solar cell having the structure shown in FIG. 6 is produced, by the sputtering apparatus in the present embodiment, the energy level caused by impurities in the semiconductor layers 10, 12, 13, 17 can be reduced, so that the recombination of holes and electrons is suppressed, making it possible to improve the solar cell in conversion efficiency.

Further, the section on the outer periphery side of the target has a straight form and hence, unlike the construction of FIG. 11, a corner 92 at the surface portion of the target piece 22a has no acute angle. Therefore, even when a sintered target, such as ITO, is formed from these target pieces, there is no problem in that the target is likely to suffer the formation of a crack. A corner 93 of the target piece 22b has an acute angle, but is near the backing tube 60 and obtains a large cooling effect, and therefore it is unlikely that a crack is formed to cause the target to be fractured.

Thus, there is no problem in that the target is fractured, during the production and the production apparatus must be stopped, and deposition with high productivity by the sputtering apparatus can be achieved.

A distance D of the tapered section 94 from the bonding material 61 is described below.

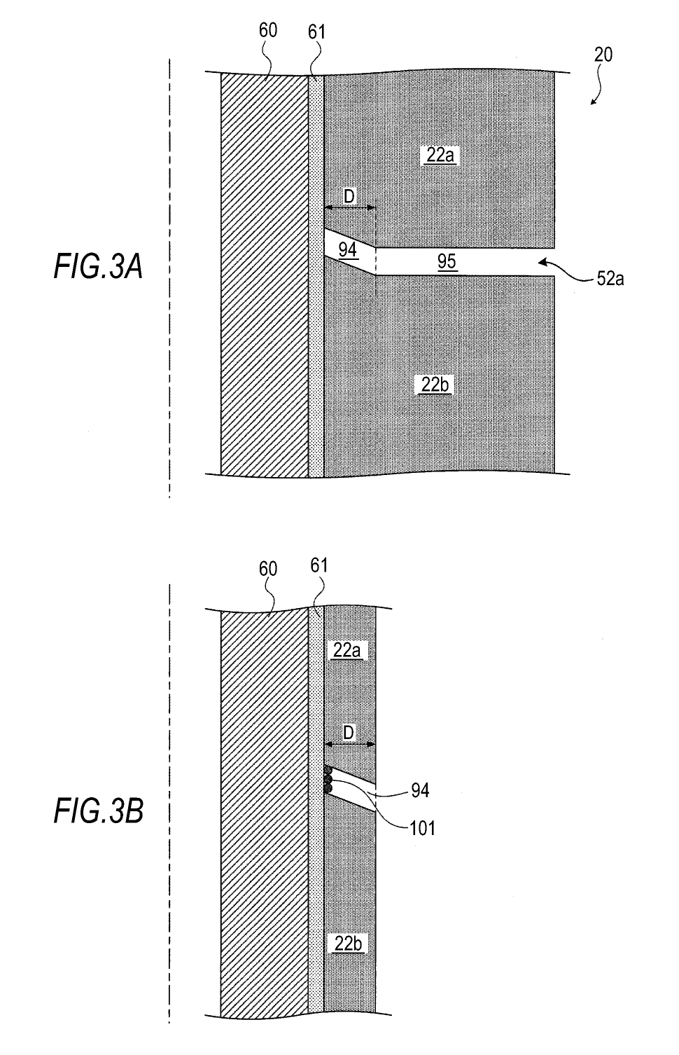

In the sputtering apparatus, the target 20 is consumed as the production proceeds. FIG. 3A shows the target 20 on the initial stage at the start of the operation. The target is in such an initial state, and, as the production proceeds, the target is consumed and becomes in the form shown in FIG. 3B. Particularly, with respect to the rotary cylindrical target, the whole of the target is uniformly consumed. When the target is completely consumed, the bonding material is disadvantageonsly sputtered. Therefore, generally, at a time when a small amount of the target material remains, the target is replaced by another. Taking into consideration the dispersion of the consumption of the target in the production, the target is replaced by another at a time when, generally, the target material having a thickness of 1 to 2 mm remains.

When the distance D is consistently 1 to 2 mm, which corresponds to the thickness for the replacement of the target, the above-mentioned effect in which all the argon ions are caused to move in the same direction in the straight portion can be exhibited over the period of time during which the target is used, preventing the bonding material between the target pieces from being sputtered. Immediately before the replacement of the target, the effect in which all the argon ions are caused to move in the same direction in the straight portion is small, but until then, the tapered portion is sputtered and deposited, and the resultant target material 101 can prevent the bonding material between the target pieces from being sputtered.

As described above, in the sputtering method using the rotary cylindrical target 20 having the structure shown in FIG. 1, the contamination by the bonding material, can be suppressed, making it possible to produce a solar cell having high conversion efficiency. Further, the sputtering apparatus having the sputtering target of the invention is free from a problem in that the operation of the apparatus is stopped due to the formation of a nodule or the target fracture, enabling the production of a solar cell with high productivity.

In the present embodiment, the gap is described using the slope θ between the straight section 95 and the tapered section 94. The angle of the slope can also be expressed by an angle α between the plane of the straight portion 95a and the plane of the tapered portion 94a of one target piece 22a constituting the gap. The angle α between these planes is 90 to less than 180° as shown in FIG. 1.

### SECOND EMBODIMENT

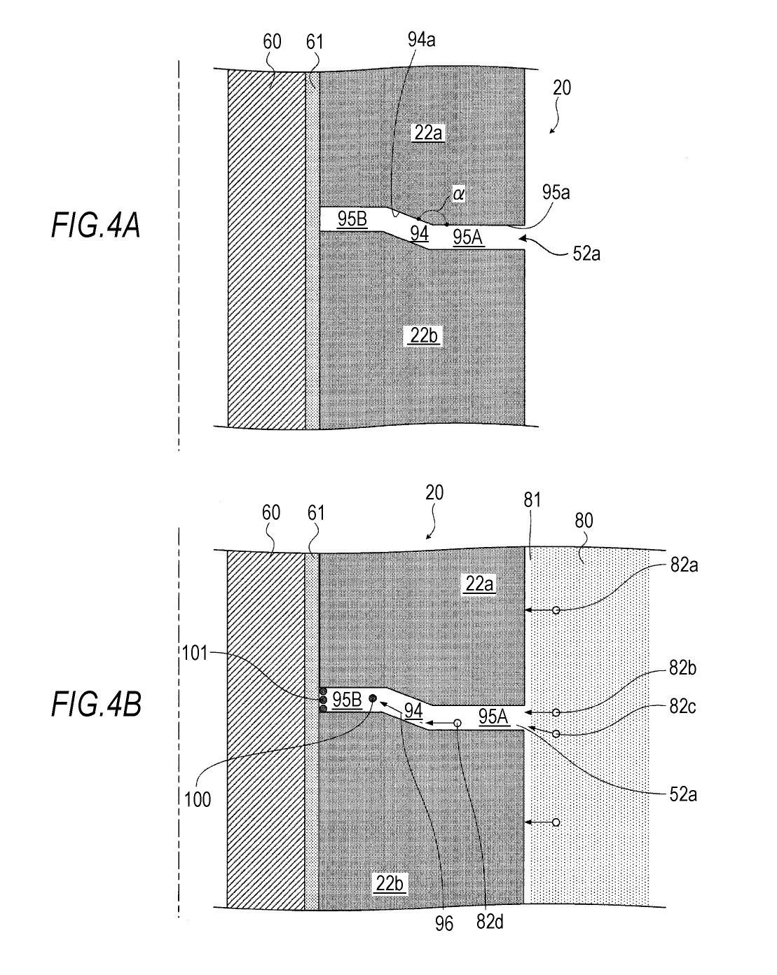

FIG. 4A shows a second embodiment of the invention.

In the first embodiment, the gap 52a is formed from the straight section 95 and the tapered section 94 connected to the straight section 95. In the second embodiment, a gap 52a is formed from a straight section 95A, and a tapered section 94 and a straight section 95B both connected to the straight section 95A. The construction in the second embodiment is the same as that in the first embodiment except for this structure.

The straight section 95A has one end which opens to the outside at the outer periphery of target pieces 22a, 22b, and has another end which extends in straight line toward a cylindrical backing tube 60. The tapered section 94, which continues to the another end of the straight section 95A, slopes at an angle θ (=5 to 30°) to the straight section 95A and extends toward the backing tube 60.

The straight section 95B is positioned between the end of the tapered section 94 on the backing tube 60 side and the backing tube 60, and has one end which is connected to the tapered section 94 and has another end which opens at the inner periphery of the target pieces 22a, 22b.

As mentioned above, the straight section 95B is formed so as to continue to the tapered section 94, and therefore there is no portion having an acute angle, which corresponds to the corner 93 shown in FIG. 2. In other words, there is no need to process the target piece, which is easily fractured, into an acute angle, and therefore there is no fear that a crack is formed in the target being processed. By virtue of this, the target is more unlikely to be fractured than that of the first embodiment, so that the operating efficiency of the apparatus is improved. As a result, high productivity can be achieved.

When an angle α between the plane of the straight portion 95a of the target piece 22a forming the straight section 95A and the plane of the tapered portion 94a of the target piece 22a forming the tapered section 94 is 90° or less, an effect becomes poor in which the argon ions 82d, which have been caused to move in the same direction in the straight section 95A and have reached the tapered section 94, sputter the target member and the resultant target member 100 is deposited on the bonding portion 101 in the target gap to cover the bonding material, preventing the bonding material from being sputtered. The reason for this is as follows. When argon ions strike the target in the direction perpendicular to the target, the angle distribution of the particles sputtered from the surface of the target is according to the cosine rule, and therefore there is almost no particle sputtered in the direction parallel to the plane of the target.

For the above-mentioned reason, the angle α between the plane of the straight portion 95a of the target piece 22a forming the straight section 95A and the plane of the tapered portion 94 of the target piece 22a forming the tapered section 94 is desirably 90 to less than 180°.

Also in the second embodiment, the straight section 95A is desirably longer. When the straight section is longer, the above-mentioned effect in which all the argon ions are caused to move in the same direction in the straight section can be exhibited, over most of the period of time during which the target is used, preventing the bonding material between the target pieces from being sputtered by the argon ions having an angle indicated by reference numeral 82c in FIG. 2. Immediately before the replacement of the target, the effect in which ail the argon ions are caused to move in the same direction in the straight section is small, but until then, the tapered section is sputtered and deposited, and the resultant target material 101 can prevent the bonding material between the target pieces from being sputtered.

The length of the straight section 95 is appropriately selected depending on the processability determined from the brittleness of the target material, and is desirably ½ or more of the thickness of the target.

As described above, in the invention, the contamination by the bonding material can be suppressed, making it possible to produce a solar cell having high conversion efficiency. Further, the sputtering apparatus having the sputtering target of the invention is free from a problem in that the operation of the apparatus is stopped due to the formation of a nodule or the target fracture, enabling the production of a solar cell with high productivity.

### THIRD EMBODIMENT

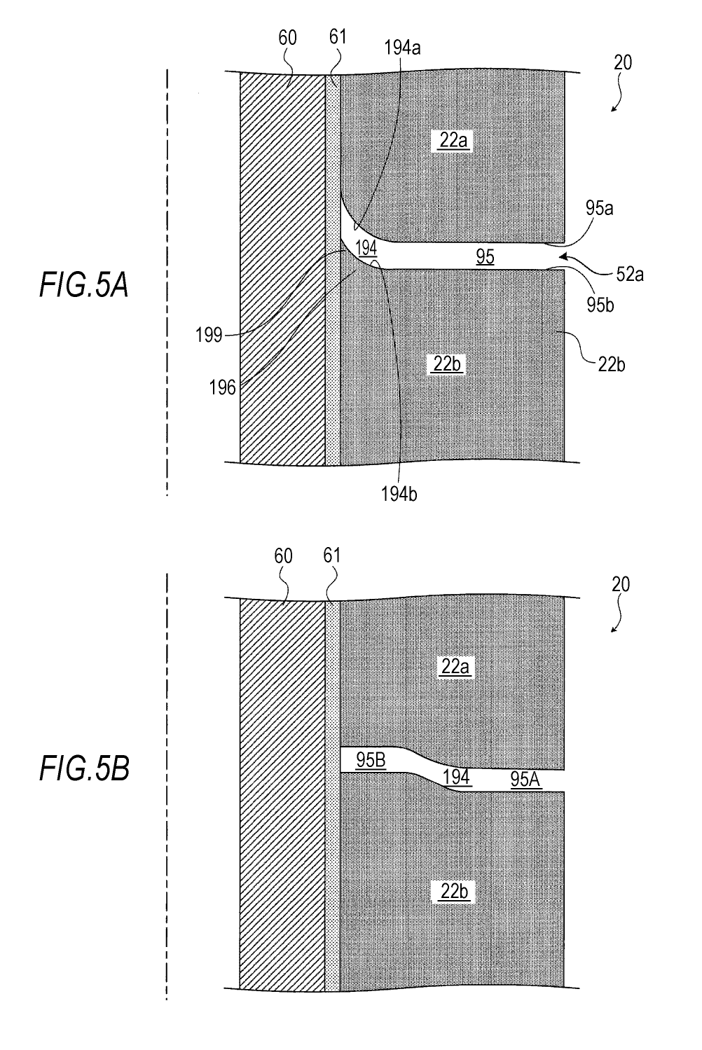

A third embodiment of the invention is described with reference to FIG. 5.

In FIG. 5 and FIGS. 3 and 4, like constitutional elements are indicated by like reference numerals.

The sputtering target of the third embodiment shown in FIG. 5A is a rotary cylindrical sputtering target having a plurality of target pieces 22a, 22b bonded to a cylindrical backing tube 60, wherein the shape of the end face of the target pieces is formed from a straight section 95 which extends from the surface of the target toward the center of rotation, and a curved section 194 which continues to the straight section.

The end face of the target piece 22a opposite the end face of the target piece 22b is formed from a straight portion 95a and a curved portion 194a. The end face of the target piece 22b opposite the end face of the target piece 22a is formed from a straight portion 95b and a curved portion 194b.

The straight section 95 is formed from the straight portion 95a of the target piece 22a and the straight portion 95b of the target piece 22b. The curved section 194 is formed from the curved portion 194a of the target piece 22a and the curved portion 194b of the target piece 22b. Further, the curved portion 194b of the target piece 22b is disposed on the extension of the straight portion 95a of the target piece 22a.

In the invention, the curved portion which continues to the straight portion means a point of the connection between the straight section 95 and the curved section 194, at which the slope of the curved section 194 in the direction of the straight section 95 is 0.

In this construction, all the argon ions are caused to move in the same direction in the straight section 95 and then enter the curved section 194, and therefore there is almost no possibility that the argon ions having an angle indicated by reference numeral 82c in FIG. 2 reach the bonding material to sputter the bonding material. Further, the argon ions caused to move in the same direction in the straight section 95 sputter the curved portion 194b, and therefore the sputtered target material is deposited on the bonding material 61 in the target gap, preventing the bonding material from being sputtered. As a result, the quality of deposition can be improved. Furthermore, in the above-mentioned embodiments, the portion of connection of the straight section 95 and the tapered, section 94 and the portion of connection of the straight section 95B and the tapered section 94 have an angular shape, but, in the present embodiment, the portion of connection of the straight section 95 and the curved section 194 is processed into a shape which is not angular, and therefore there is no fear that a crack is formed in the target being processed.

By virtue of this, the target is more unlikely to be fractured than that of the second embodiment, so that the operating efficiency of the apparatus is improved. As a result, high productivity can be achieved.

The portion indicated by reference numeral 199 in FIG. 5A has an acute angle, and therefore possibly causes a crack in the target being processed. However, this portion is near the backing tube, and obtains a large cooling effect, as compared to a portion 198 far from the backing tube, and thus it is unlikely that the target is fractured.

FIG. 5B shows an example of the modification of FIG. 5A.

In FIG. 5A, the gap 52a has a single straight section. In the example of the modification shown in FIG. 5B, the gap has a straight section 95B which continues to the curved section 194 shown in FIG. 5A, and which extends from the surface of the target toward the center of rotation.

By virtue of this construction, there is no portion having an acute angle, which corresponds to a portion 196 shown in FIG. 5A, and therefore the target is more unlikely to be fractured due to the formation of a crack than that of the construction of FIG. 5A.

Also in the third embodiment, the straight section 95 is desirably longer. When the straight section 95 is longer, the effect in which all the argon ions are caused to move in the same direction in the straight section 95 can be exhibited over most of the period of time during which the target is used, preventing the bonding material between the target pieces from being sputtered by the argon ions having an angle indicated by reference numeral 82c in FIG. 2. Immediately before the replacement of the target, the effect in which all the argon ions are caused to move in the same direction in the straight section is small, but until then, the curved portion is sputtered and deposited, and the resultant target material 101 can prevent the bonding material between the target pieces from being sputtered.

The length of the straight section 95 is appropriately selected depending on the processability determined from the brittleness of the target material, and is desirably ½ or more of the thickness of the target. When using a target material which is unlikely to suffer the formation of a crack upon processing, the construction of FIG. 5A is desired because the length of the straight section 95A can be longer.

As described above, in the invention, the contamination by the bonding material can be suppressed, making it possible to produce a solar ceil having high conversion efficiency. Further, the sputtering apparatus having the sputtering target of the invention is free from a problem in that the operation of the apparatus is stopped due to the formation of a nodule or the target fracture, enabling the production of a solar cell with high productivity.

### INDUSTRIAL APPLICABILITY

The invention can be applied to a sputtering target for a sputtering apparatus used in the production of a solar cell using single crystal or polycrystal.

What is claimed is:

1. A sputtering target having a plurality of target pieces bonded to a periphery of a cylindrical backing tube,
the target pieces being arranged in a direction of an axis of the tube so that a gap is formed between adjacent target pieces,
the gap having a straight section which extends from the outer periphery of the target pieces toward the axis of the tube, and a tapered section which is positioned between the straight section and the tube, and which slopes in a longitudinal direction of the straight section.

2. The sputtering target according to claim 1, wherein the gap is formed so that the tapered section continues to the straight section.

3. The sputtering target according to claim 1, wherein an end face of one of the adjacent target pieces, which constitutes the tapered section, is disposed on an extension of an end face of another one of the adjacent target pieces, which constitutes the straight section.

4. A sputtering target having a plurality of target pieces bonded to a periphery of a cylindrical backing tube,
the target pieces being arranged in a direction of an axis of the tube so that a gap is formed between adjacent target pieces,
the gap having a straight section which extends from the outer periphery of the target pieces toward the axis of the tube, and a curved section which is positioned between the straight section and the tube, and which is curved in the axis direction of the tube.

5. The sputtering target according to claim 4, wherein the gap is formed so that the curved section continues to the straight section.

6. The sputtering target according to claim 4, wherein an end face of one of the adjacent target pieces, which constitutes the curved section, is disposed on an extension of the end face of another one of the adjacent target pieces, which constitutes the straight section.

7. A sputtering apparatus having the sputtering target according to claim 1.

8. A sputtering method which performs deposition using the sputtering target according to claim 1.

9. A sputtering target having a plurality of target pieces bonded to a periphery of a cylindrical backing tube,
the target pieces being arranged so that a gap is formed between adjacent target pieces,
the gap including a first portion substantially perpendicular to the periphery of the cylindrical backing tube, and a second portion non-perpendicular to the periphery of the cylindrical backing tube and extending from the first portion towards the periphery of the cylindrical backing tube.
